(19) United States
(12) Patent Application Publication
(10) Pub. No.: US 2024/0345142 A1
(43) Pub. Date: Oct. 17, 2024

(54) SYSTEMS AND METHODS FOR TIME-SYNCHRONIZED TOPOLOGY AND STATE ESTIMATION IN REAL-TIME UNOBSERVABLE DISTRIBUTION SYSTEMS

(71) Applicant: Arizona Board of Regents on Behalf of Arizona State University, Tempe, AZ (US)

(72) Inventors: Anamitra Pal, Gilbert, AZ (US); Behrouz Azimian, Tempe, AZ (US); Lang Tong, Ithaca, NY (US)

(73) Assignees: Arizona Board of Regents on Behalf of Arizona State University, Tempe, AZ (US); Cornell University, Ithaca, NY (US)

(21) Appl. No.: 18/638,531

(22) Filed: Apr. 17, 2024

Related U.S. Application Data
(60) Provisional application No. 63/459,791, filed on Apr. 17, 2023.

(51) Int. Cl. G01R 19/25

(52) U.S. Cl. CPC G01R 19/2513

(57) ABSTRACT

Time-synchronized state estimation for reconfigurable distribution systems is challenging because of limited real-time observability. A system addresses this challenge by formulating a deep learning (DL)-based approach for topology identification (TI) and unbalanced three-phase distribution system state estimation (DSSE). Two deep neural networks (DNNs) are trained for time-synchronized DNN-based TI and DSSE, respectively, for systems that are incompletely observed by synchrophasor measurement devices (SMDs) in real-time. A data-driven approach for judicious SMD placement to facilitate reliable TI and DSSE is also developed.

### CROSS REFERENCE TO RELATED APPLICATIONS

This is a U.S. non-provisional patent application that claims benefit to U.S. Provisional Application Ser. No. 63/459,791, filed on Apr. 17, 2023, which is herein incorporated by reference in its entirety.

### GOVERNMENT SUPPORT

This invention was made with government support under DE-AR0001001 awarded by the Department of Energy. The government has certain rights in the invention.

### FIELD

The present disclosure generally relates to utility distribution networks, and in particular, to a system and associated method for time-synchronized topology and state estimation in real-time unobservable utility distribution systems.

### BACKGROUND

State and topology estimation in utility distribution systems is imperative to ensure safe and effective operation. One challenge with this task is that a utility distribution network may not be equipped with a sufficient quantity of synchrophasor measurement devices and/or other sensors required for classical state estimation.

It is with these observations in mind, among others, that various aspects of the present disclosure were conceived and developed.

### BRIEF DESCRIPTION OF THE DRAWINGS

The present patent or application file contains at least one drawing executed in color. Copies of this patent or patent application publication with color drawing(s) will be provided by the Office upon request and payment of the necessary fee.

FIG. 1A is a simplified block diagram showing a computer-implemented system for distribution system state estimation that adapts to a present topology of a distribution network;

FIG. 1B is a simplified diagram showing an architecture of a first deep neural network (“DNN-TI”) of the system of FIG. 1A for identifying a present topology of a distribution network;

FIG. 1C is a simplified diagram showing an architecture of a second deep neural network (“DNN-DSSE”) for estimating a state vector of a distribution network;

FIG. 2 is a diagram illustrating an implementation process of the system of FIGS. 1A-1C including an “offline learning” training phase for training the first DNN and the second DNN to identify topologies of a distribution network and estimate a state vector of a base topology, and an “online learning” phase for identifying a present topology of the distribution network using the first DNN, fine-tuning parameters of the second DNN to accommodate the present topology when necessary, and estimating a state vector of the distribution network under the present topology;

FIG. 3 is a diagram showing a real-world distribution system with one synchrophasor measurement device at a feeder-head;

FIG. 4 is a diagram showing a 240-node distribution with six synchrophasor measurement devices for DSSE and topology identification;

FIG. 5 is a graphical representation showing results of a comparative study of DNN-based DSSE with and without fine-tuning of the DNN;

FIG. 6 is a simplified diagram showing an example computing system for implementation of the system of FIG. 1A.

Corresponding reference characters indicate corresponding elements among the view of the drawings. The headings used in the figures do not limit the scope of the claims.

### DETAILED DESCRIPTION

A system and associated methods for deep neural network (DNN)-based distribution system state estimation (DSSE) of real-time unobservable systems are disclosed herein. The system aims to perform DNN-based DSSE under varying topologies using transfer learning.

Real-time monitoring and control of distribution networks was traditionally deemed unnecessary because it had radial configuration, unidirectional power flows, and predictable load patterns. However, the fast growth of behind-the-meter (BTM) generation, particularly solar photovoltaic (PV), electric vehicles, and storage, is transitioning the distribution system from a passive load-serving entity to an active market-ready entity, whose reliable and secure operation necessitates real-time situational awareness. Phasor measurement units (PMUs), distribution-PMUs (D-PMUs), and/or micro-PMUs, collectively referred to as synchrophasor measurement devices (SMDs) in this disclosure, have been introduced into the distribution system to provide fast (sub-second) situational awareness by enabling time-synchronized estimation. However, due to the high cost of installation, the numbers of SMDs in a typical distribution network are not large enough to provide an independent assessment of the system state. The assumption of Gaussian noise in synchrophasor measurements has also been disproved recently.

At the same time, modern distribution systems are being equipped with advanced metering infrastructure (AMI) in the form of smart meters. Hence, a combination of smart meter data with SMD data for facilitating distribution system state estimation (DSSE), particularly in three-phase unbalanced distribution systems, has also been tried out. However, smart meters typically measure energy consumption from 15 minute to hourly time intervals and report their readings after a few hours or even a few days. These two aspects make smart meter data unsuitable for real-time DSSE. Moreover, smart meter data are not time-synchronized by default, which makes their direct integration with SMD data a statistical challenge. Real-time DSSE is possible using SMDs alone. However, as mentioned above, placing large numbers of SMDs in a distribution network is cost prohibitive.

Lastly, topology of a distribution network changes with time. This implies that impacts of changes in the configuration of the distribution system must be considered when performing DSSE. Although approaches have been proposed in the past to estimate topology and state estimates independently, a joint framework for identifying the topology and estimating the states at high-speed in distribution systems that are unobservable by SMDs has not been proposed before.

One implementation of the system is applied to estimate voltages in distribution systems under extremely unobserved conditions (e.g., with few synchrophasor measurement devices available). The system can represent voltage phasors in an unbalanced distribution system at node g as x_{g}=[x_{g}¹, x_{g}², x_{g}³]^{T} where the superscripts are phase indices, and x_{g}^{k}=V_{g}^{k}<θ_{g}^{k}, where V_{g}^{k} and θ_{g}^{k} are voltage phase magnitude and voltage phase angle, respectively, of phase k at node g. The overall system state x=[x₁, . . . , xₙ]^{T} is the column vector that includes voltage phasors of all the nodes, where the unbalanced distribution system includes a plurality of nodes (e.g., n total nodes where g∈[1, n]). Similarly, all available measurements can be stacked to create the column vector z=[z₁, . . . , zₘ]^{T} (e.g., for m total sensors). In classical state estimation, the relationship between the measurements and the states is given by:

$$z = h ( x ) + e \qquad ( 1 )$$

where h(⋅) is the measurement function, whose structure depends on the type of sensor(s) providing the measurements as well as the observability of the unbalanced distribution system by the sensor(s), and e represents the noise in the measurements. Time-synchronized state estimation in distribution networks using classical approaches, such as least-squares, can be formulated as shown in (2) below.

$${\hat{x}}_{wls} ( z ) = arg {min}_{x} {‖ z - h ( x ) ‖}^{2} \qquad ( 2 )$$

Classical state estimation requires the distribution system to be completely observed by synchrophasor measurement devices (SMDs). In other words, m>>n. However, it is highly unlikely that, at least in the near future, a distribution system will be equipped with as many SMDs as is required for complete observation of the distribution system by them alone. To circumvent the problem of scarcity of SMDs and other sensors for performing time-synchronized DSSE, the system disclosed herein applies a Bayesian approach in which a state, x, and a measurement, z, are treated as random variables. A minimum mean squared error (MMSE) estimator is applied to minimize the estimation error as shown in (3) below.

$${min}_{\hat{x} ( \cdot )} 𝔼 ( {‖ z - h ( x ) ‖}^{2} ) ⇒ {\hat{x}}^{*} ( z ) = 𝔼 ( x \vert z ) \qquad ( 3 )$$

The MMSE estimator directly minimizes the estimation error while classical estimators, such as least-squares, minimize the modeling error embedded via the measurement function h(⋅) that relates the measurements with the states. By circumventing the need for the measurement function using the Bayesian MMSE state estimator, the system disclosed herein bypasses real-time observability requirements. Note that in (3), there are two underlying challenges to computing the conditional mean. First, the conditional expectation, which is defined by:

$$𝔼 ( x \vert z ) = {\int }_{- ∞}^{+ ∞} xp ( x \vert z ) dx \qquad ( 4 )$$

requires the knowledge of p(x|z), which is the joint probability density function (PDF) between x and z. When the number of SMDs is scarce, the PDF between SMD data and all the voltage phasors (i.e., the states of the distribution system) is unknown or impossible to specify. This makes direct computation of \hat{x}*(z) intractable. Second, even if the underlying joint PDF is known, finding a closed-form solution for (4) can be difficult. A DNN can be used to approximate the MMSE state estimator as a DNN has excellent approximation capabilities; e.g., the DNN for DSSE developed here finds a mapping (denoted by [symbol] (⋅)) that relates x and z.

Even if a DNN can successfully approximate [symbol] (x|z) for a given topology, once the topology changes, the distribution of the inputs (i.e., SMD measurements) for which the DNN had been trained for, change. This is best realized from the fact that the direction of the currents in a distribution feeder can reverse when topology change occurs due to status changes of the switches. Thus, there is a need to update the trained DNN after topology changes. One way to do this is to train the DNN for DSSE afresh for every new topology. However, doing so may take a very long time. An alternate (better) solution is to employ transfer learning to transfer the knowledge gained from the old topology to the new topology.

Transfer learning improves the learning of the target prediction function in the target domain using the knowledge available in the source domain and task. A domain [symbol] comprises two parts: a feature space, [symbol] , and a marginal probability distribution, P(z). Given [symbol] , a task [symbol] includes two parts: a label space, [symbol] , and an objective prediction (mapping) function, [symbol] (⋅). In DNN-based DSSE under varying topologies, [symbol] does not change as the same SMD measurements will be used for different topologies. However, P(z) changes because loads are served by different paths when topology changes, i.e., when [symbol] _{S}≠ [symbol] _{T}. Similarly, [symbol] does not change because the number of states (i.e., voltage phasor at each node) and their nature are the same. However, [symbol] (⋅), must be retrained for the target domain, i.e., [symbol] ≠ [symbol] . Now, it is clear from this problem set-up that the objective is to induce transfer of knowledge gained from [symbol] _{S} and [symbol] (old topology) to [symbol] _{T} and [symbol] (new topology). Thus, the system can employ inductive transfer learning to attain the desired objective. Four approaches have been proposed for implementing inductive transfer learning, namely, feature-representation transfer, instance transfer, relational-knowledge transfer, and parameter transfer. Here, the system can apply parameter transfer to update the DNN for DSSE as the DNN's parameters can be used for multiple domains.

Parameter-based transfer learning methods include parameter-sharing and fine-tuning. Parameter-sharing assumes that the parameters are highly transferable due to which the parameters in the source domain can be directly copied to the target domain, where they are kept “frozen”. Fine-tuning assumes that the parameters in the source domain are useful, but they must be trained with limited target domain data to better adapt to the target domain. Since there is no guarantee that the parameters of the DNN-based DSSE will be highly transferable for different topologies, fine-tuning is used here to update the weights of the DNN for DSSE when topology changes. Essentially, fine-tuning provides a more effective initialization (than random initialization) by using the weights from the previously well-trained DNN. By doing this, the system bypasses the need for large amounts of data (and time) for DNN re-training.

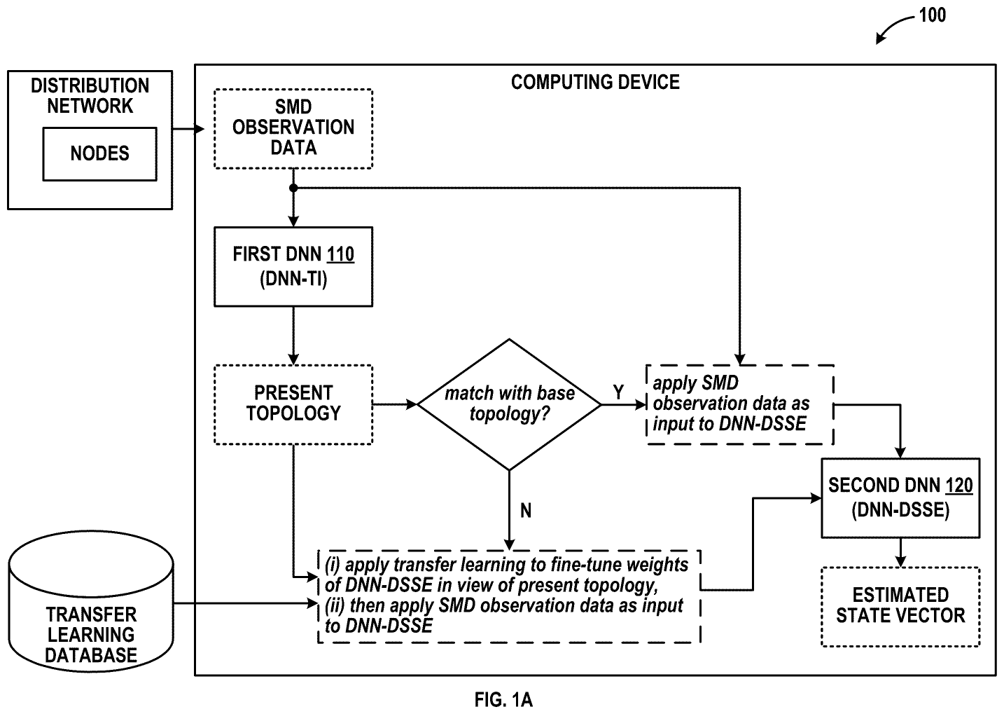

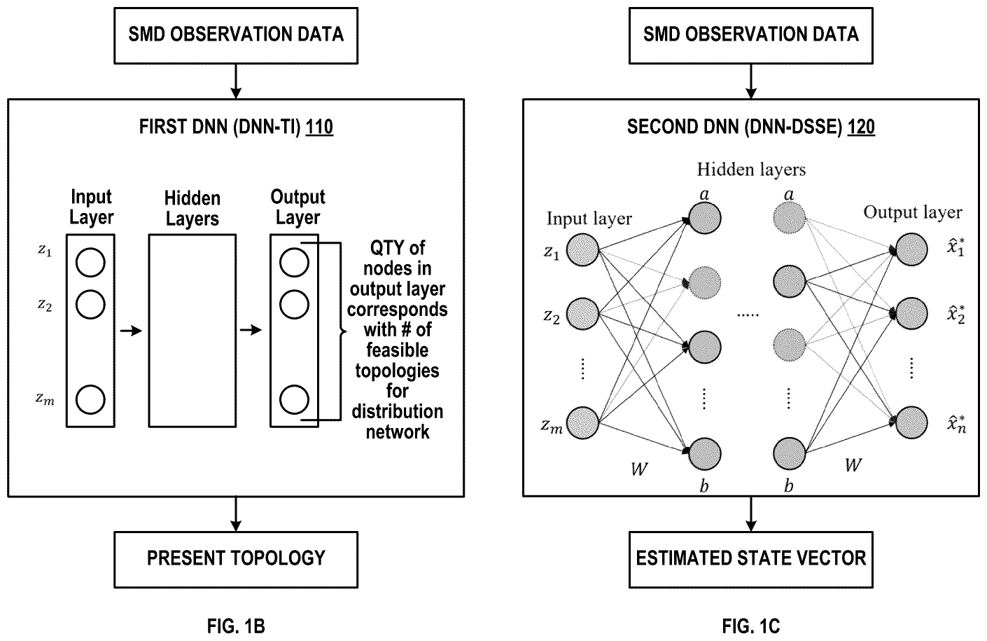

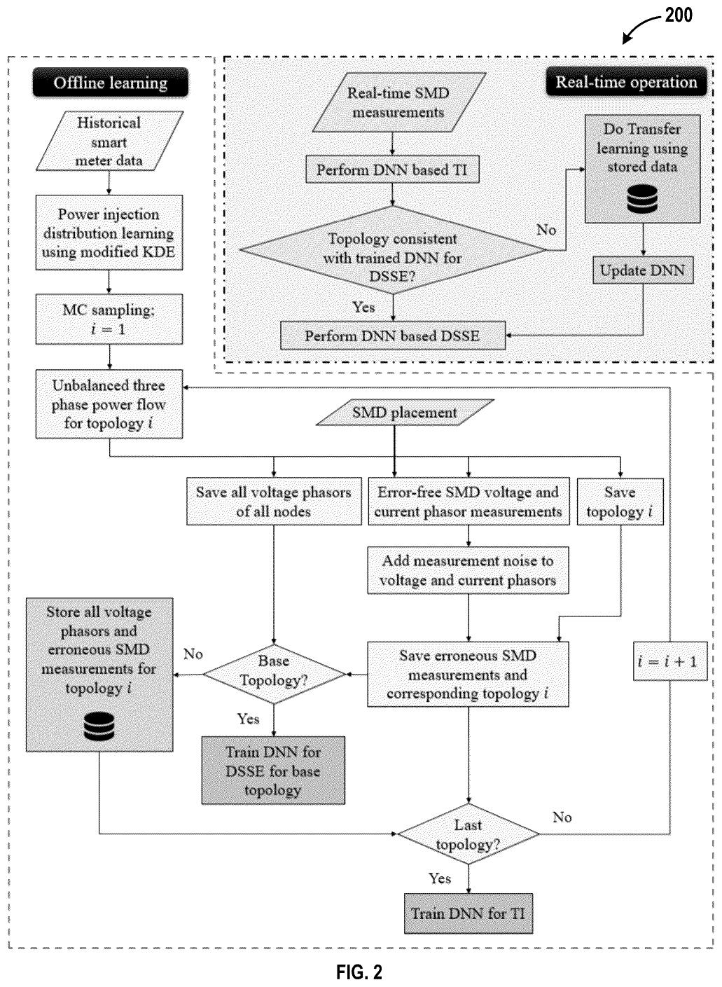

FIGS. 1A-1C show a system 100 for DSSE according to the concepts outlined herein. The system 100 includes an offline learning portion and a real-time operation portion, in which the processes applied by each are shown in FIG. 2. The offline learning portion and a real-time operation portion communicate with a first DNN 110 for topology identification (TI) that determines a topology of a distribution system (e.g., to ensure that the DNN for DSSE can accommodate a distribution system with a modified topology), and a second DNN 120 for DSSE discussed above. The second DNN 120 can be updated during real-time operation using transfer learning—this is where the first DNN 110 is useful. The first DNN 110 can determine if the topology of the distribution system is consistent with a training topology used to train the second DNN 120 for distribution system state estimation and based on the determination the system 100 can update second DNN 120 using a transfer learning methodology.

The basic structure of the second DNN 120 for DSSE is shown in FIG. 1C. Inputs to the second DNN 120 are measurements z, obtained from SMDs, and outputs from the second DNN 120 are estimated voltage phasors, \hat{x}*(z); m refers to a size of z; n refers to the total number of states to be estimated; a denotes an activation function; b denotes a bias; and W refers to weights conveying outputs of previous neurons of a previous layer of the second DNN 120 to the neurons of a next layer of the second DNN 120. Dropout is also applied to avoid overfitting; its effect is shown in FIG. 1C by dotting some of the circles in the hidden layers. Note that for a distribution network that is incompletely observed in real-time, n>>m. The number of neurons and hidden layers are hyperparameters that can be tuned offline. A rectified linear unit (ReLU) activation function is used for hidden layers of the second DNN 120, while a linear activation function is used for an output layer of the second DNN 120. A loss function is chosen to be the empirical mean-squared error. During the offline training process the weights of the second DNN 120 are optimized to minimize the mean-squared error using a backpropagation algorithm. In real-time operation, SMD data is fed into the (trained, feed-forward) second DNN 120 and the estimated state, \hat{x}*, is obtained.

The second DNN 120 for DSSE shown in FIGS. 1A-1C can be trained based on the assumption that the topology of the distribution system is known and fixed. However, when a topology change occurs, the second DNN 120, which is trained for the old topology, will receive test data from another feature space that corresponds to the new topology. As this might lower the performance of the second DNN 120, a sequential procedure is adopted in which the new topology is identified first by the first DNN 110 (namely, a DNN for topology identification (TI)), and the second DNN 120 for DSSE is updated afterwards based on the identified (new) topology.

As opposed to the second DNN 120 that was built for DSSE and apples regression-based operations to estimate states, the first DNN 110 (shown in FIG. 1B) is a classification DNN built for DNN-based TI in which the measurements from sparsely placed SMDs are used to track the switch statuses in real-time. In the first DNN 110 for TI, the number of neurons in the output layer is equal to the number of feasible topologies in the distribution system, the SoftMax function is used as the activation function for the output layer, while the categorical cross-entropy is chosen to be the loss function (the inputs and activation function for the hidden layers are the same as the second DNN 120 for DSSE). Feasible topologies refer to those switch configurations for which the system does not split into islanded sub-systems. In other words, feasible topologies constitute those topologies for which some of the power flow directions may change, but no node is completely disconnected from the rest of the system. For training the first DNN 110 for TI, the database generation process is repeated for all feasible topologies. A distinct advantage of the first DNN 110 is that it only requires high-speed time-synchronized SMD measurements for online operation as opposed to other methods, which assumed availability of smart meter measurements in real-time.

It is possible that a distribution system may not have any SMD to begin with or the number of SMDs may not be sufficient to perform DNN-based TI and/or DSSE. For such situations, the following algorithm is proposed to place SMDs in the system. In this algorithm, Budget refers to the budget allocated for SMD placement, TI_{accuracy} and DSSE_{accuracy} are the minimum desired accuracy for TI and DSSE, respectively, DSSE_{corr} is the minimum correlation between each pair of nodes, and M is the number of nodes in the system. For placing SMDs for DNN-based TI, a greedy search algorithm called sequential forward selection was used, while the correlation between the nodes, which was needed for placing SMDs for DNN-based DSSE, was determined using Spearman correlation coefficient (SCC).

Algorithm: Integrated SMD placement for DNN-based TI and DSSE
Algorithm: Integrated SMD placement for DNN-based TI and DSSE

Inputs: Budget, TI_{accuracy}, DSSE_{accuracy}, DSSE_{corr}, M
Output: Location of the SMDs

| A. | | SMD placement for TI: |
|---|---|---|
| | i. | N_{feature} = 1 |
| | ii. | If there are no switches in the system, go to (B) |
| | iii. | Apply sequential forward selection with N_{feature} features to place SMDs |
| | iv. | If SMD cost ≥ Budget, then End, else set N_{feature} = N_{feature} + 1 |
| | v. | If TI_{accuracy} is satisfied, then go to (B), else go to (A.iii) |
| B. | | SMD placement for DSSE: |
| | i. | N_{cluster} = 1 |
| | ii. | Calculate SCC between each voltage phasor Vᵢⱼ^{kl} ∀i ∈ {A, B, C}, ∀j ∈ {mag, ang}, and ∀k, l ∈ |
| | | {1,..., M} |
| | iii. | If SCC ∀k, l ∈ {1,..., M} is greater than DSSE_{corr} ∀i ∈ {A, B, C} and ∀j ∈ {mag, ang}, then go to |
| | | (B.vii.) |
| | iv. | N_{cluster} = N_{cluster} + 1 |
| | v. | Apply hierarchical clustering to each SCC matrix ∀i ∈ {A, B, C} & ∀j ∈ {mag, ang} |
| | vi. | Find common node in each cluster for each SCC and place SMD on this node |
| | vii. | If DSSE_{accuracy} is satisfied or SMD cost ≥ Budget, then End, else go to (B.iv.) |

### Implementation and Results

An overview of a process 200 applied by the system 100 disclosed herein is shown in FIG. 2. The process 200 can be split into offline learning and real-time operation. In offline learning stage, only slow-time scale smart meter data is used, while in real-time operation a few SMD measurements are relied on to carry out DSSE.

The process 200 includes: receiving a set of real-time SMD measurements from a distribution system; applying the set of real-time SMD measurements as input to a first deep neural network for topology identification of the distribution system to determine a topology of the distribution system; and applying the set of real-time SMD measurements as input to a second deep neural network for distribution system state estimation of the distribution system, where an output of the second deep neural network includes a set of estimated states of the distribution system based on the set of real-time SMD measurements. The first deep neural network is a classification-based deep neural network configured for determining the topology of the distribution system based on the set of real-time SMD measurements. The second deep neural network is a regression-based deep neural network configured for estimating a state and a measurement of a node of the distribution system based on the set of real-time SMD measurements.

During real-time operation, the process 200 can include: determining, based on the output of the first deep neural network, if a topology of the distribution system is consistent with a training topology used to train the second deep neural network for distribution system state estimation; and updating the second deep neural network using a transfer learning methodology prior to application of the set of real-time SMD measurements as input to the second deep neural network.

The process 200 can also include: training the first deep neural network for topology identification and the second deep neural network for distribution system state estimation through an offline learning process that iteratively models a set of modeled SMD measurements for one or more possible topologies of the distribution network and trains the first deep neural network and the second deep neural network based on the set of modeled SMD measurements for one or more possible topologies of the distribution network. This step can further include: receiving a set of historical smart meter data for the distribution network; modeling unbalanced phase power flow for an i-th topology of the distribution network; modeling, for the i-th topology, placement of one or more modeled SMDs at one or more nodes of the distribution network; and obtaining, for the i-th topology, a set of modeled SMD measurements including modeled voltage phasor measurements and modeled current phasor measurements representing SMD measurements captured by one or more modeled SMDs at the one or more nodes of the distribution network. Based on the topology being modeled and the set of modeled SMD measurements, the process 200 can further include at least one of the following: training the second deep neural network based on the set of modeled SMD measurements for the i-th topology, the i-th topology being a base topology of the distribution network; training the first deep neural network based on the set of modeled SMD measurements for the i-th topology, the i-th topology being a last possible topology of the distribution network, and storing the set of modeled SMD measurements in association with the i-th topology.

Modeling placement of one or more modeled SMDs at one or more nodes of the distribution network includes: applying (for TI-based node selection) a sequential forward selection methodology to select the one or more nodes of the distribution network for SMD placement. Alternatively (or jointly), modeling placement of one or more modeled SMDs at one or more nodes of the distribution network includes: receiving a minimum correlation value representative of target minimum correlation between one or more nodes of the distribution network; determining a Spearman Correlation Coefficient value between each respective modeled voltage phasor measurement; constructing one or more Spearman Correlation Matrices based on the Spearman Correlation Coefficient value between each respective modeled voltage phasor measurement; applying a hierarchical clustering methodology to the one or more Spearman Correlation Matrices to obtain one or more clusters; and selecting a common node of the one or more nodes of the distribution network in each cluster of the one or more clusters for SMD placement.

Iteratively obtaining modeled SMD measurements can include: obtaining a set of modeled error-free SMD measurements including modeled error-free voltage phasor measurements and modeled error-free current phasor measurements; and adding measurement noise to the set of modeled error-free SMD measurements to obtain the set of modeled SMD measurements including the modeled voltage phasor measurements and the modeled current phasor measurements.

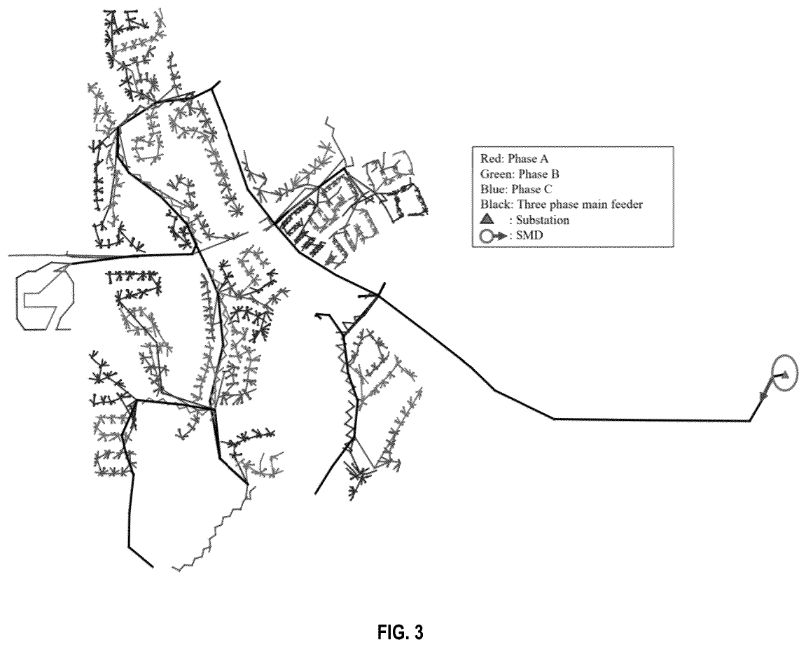

### 1. Implementation of DNN-Based DSSE for a Real-World Distribution System Located in a Metropolitan City of U.S. Southwest (See FIG. 3)

In this study, the DNN-based DSSE was tested for a real-world distribution system for which historical smart meter data was available at all the nodes and SMD measurements were only possible at the feeder-head. Note that most power utilities have real-time measurements only at the feeder-head of their distribution systems. Therefore, it was of interest to evaluate the performance of the proposed method for DSSE when SMD placement cannot be done due to budget constraints and only the existing measurements can be used. There are 648, 665, and 637 nodes in phase A, phase B, and phase C, respectively, of this distribution system, whose voltage magnitudes and angles must be estimated for different operating conditions. Additionally, this feeder is a renewable-rich distribution system with 766 household/commercial rooftop solar PV units. Therefore, this is an ideal distribution system to evaluate the performance of the proposed method for performing DSSE for a large-scale real-world distribution system with high penetration of renewable resources.

The implementation procedure shown in FIG. 2 was followed to create the required database from historical smart meter data for this distribution system and train a DNN for DSSE. The estimation errors for DNN-based DSSE are summarized in Table I for voltage magnitude and angle of each phase separately.

TABLE I
DNN-based DSSE performance with one
SMD at feeder-head

| | Phase error | Magnitude |
|---|---|---|
| Target | [degrees] | error [%] |
| Phase | MAE | MAPE |
| Phase A | 0.0098 | 0.0251 |
| Phase B | 0.0135 | 0.0245 |
| Phase C | 0.0121 | 0.0291 |

The reasonably good results reported in Table I demonstrate the applicability of the process 200 for large real-world systems. Hence, power utilities, which do not own enough SMDs to fully observe their distribution systems, can use the process 200 to perform time-synchronized DSSE.

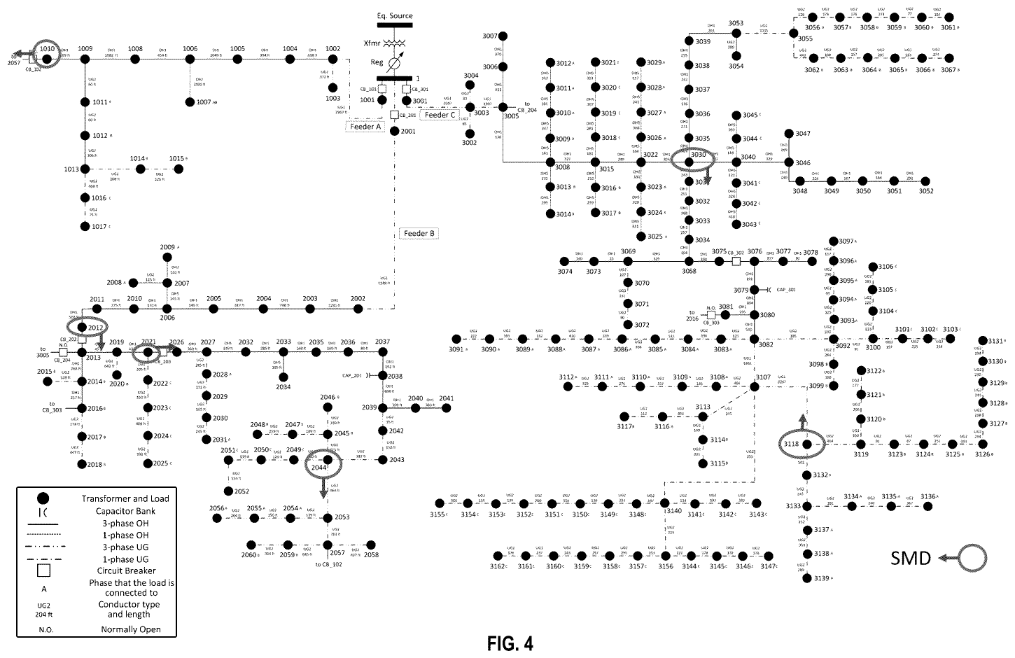

2. Implementation of Transfer Learning and DNN-Based DSSE when Topology Changes for a Real-World Distribution System Located in the U.S. Midwest (See FIG. 4).

This distribution system did not have any SMDs placed apriori. However, it has nine switches, which resulted in 84 feasible topologies. Therefore, an integrated algorithm for SMD placement was used to determine the suitable locations for placing SMDs in this distribution system for performing DNN-based TI and DSSE. Six locations were identified as shown with green ovals and red arrows in FIG. 4. With only six SMDs, the proposed DNN-based DSSE approach outperformed conventional linear state estimation (LSE), which required 113 SMDs, as shown in Table II.

TABLE II
Comparing the performance of DNN-based DSSE with
LSE for 240-node distribution system

| | Phase error | Magnitude | |
|---|---|---|---|
| | [degrees] | error [%] | |
| Method | MAE | MAPE | # SMD |
| LSE | 0.0200 | 0.0389 | 113 |
| DNN-based | 0.0179 | 0.0242 | 6 |
| DSSE | | | |

Next. It was assumed that the topologies of this distribution system are changed in accordance with Table III.

TABLE III
Switch configurations for different topologies

| Switch | Network reconfiguration | | | |
|---|---|---|---|---|
| name | T1 | T2 | T3 | T4 |
| CB_101 | 1 | 1 | 0 | 0 |
| CB_102 | 0 | 1 | 1 | 1 |
| CB_201 | 1 | 1 | 0 | 1 |
| CB_202 | 1 | 0 | 1 | 1 |
| CB_203 | 1 | 1 | 1 | 1 |
| CB_204 | 0 | 1 | 1 | 0 |
| CB_301 | 1 | 1 | 1 | 0 |
| CB_302 | 1 | 1 | 0 | 1 |
| CB_303 | 0 | 0 | 1 | 1 |

When topology changes occur, after correctly identifying the new topology using DNN-based TI (note that the DNN-based TI had 99.19% accuracy for this distribution system), the DNN trained for doing DSSE for the old topology, must be updated. As described in the process 200 (see FIG. 2), the TI and DSSE work sequentially, and Transfer learning is used to update the DNN for DSSE after the topology of the distribution system changes. In Table III, four different topologies are considered to show the ability of the process 200 in handling different system configurations. Initially, the distribution system is operating in the base topology, T1, which is radial. Next, status of three switches are changed to create a meshed network, described by T2. Then, configurations of five switches are changed to create a new topology, T3. Finally, in the fourth step, T3 changes to another topology, T4, which is different from all the previous topologies.

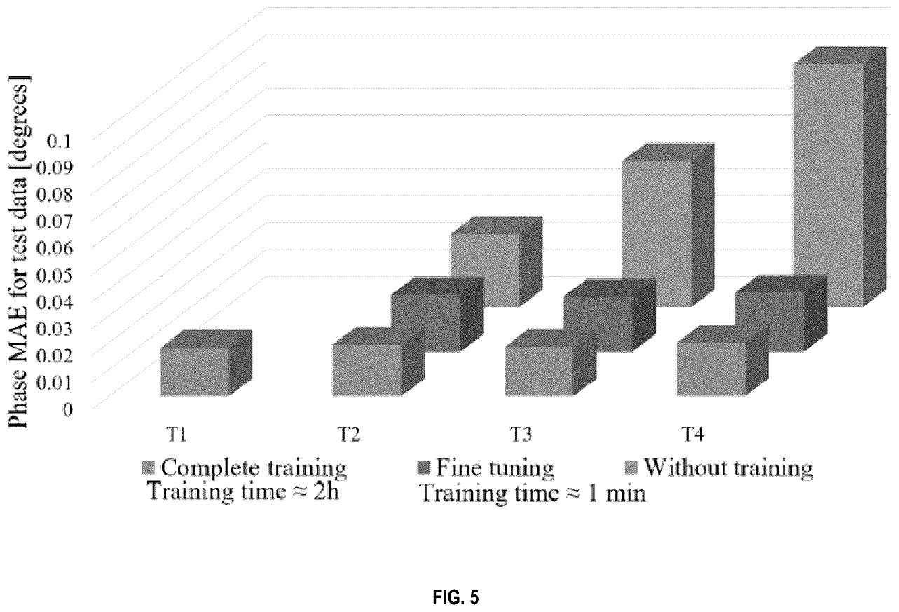

FIG. 5 presents the results for topology changes and its impact on DSSE with and without transfer learning. It can be seen from the plots that it takes about 1 minute for the fine-tuning of the DNN, while complete training for a new topology would have taken two hours. This is because 10,000 samples and 1,000 epochs were needed for training and validation of a completely new DNN for DSSE for a new topology, while by taking advantage of fine-tuning only 3,000 samples and 32 epochs were needed; i.e., the training time was reduced considerably. This is an important result because if different switching events were to manifest every few minutes, then without transfer learning fast DSSE results cannot be achieved when it is needed the most. Hence, this quick update of the DNN-based DSSE significantly improves the real-time monitoring capability of the proposed approach during switching events.

Lastly, the angle MAE results are now compared with and without fine-tuning of the DNN for DSSE. It is observed from FIG. 5 that if the old DNN for DSSE (created for T1) was used for the new topologies (T2, T3, T4), the error increases by 1.5 times for the change from T1 to T2, more than three times for the change from T1 to T3, and more than five times for the change from T1 to T4 (compare heights of orange bars and blue bars in FIG. 5), respectively. However, the state estimator performance is similar for fine-tuning and complete training (compare heights of green bars and blue bars in FIG. 5). Thus, by using transfer learning, DNN-based DSSE can be done quickly and accurately during varying network topologies.

### Computer-Implemented System

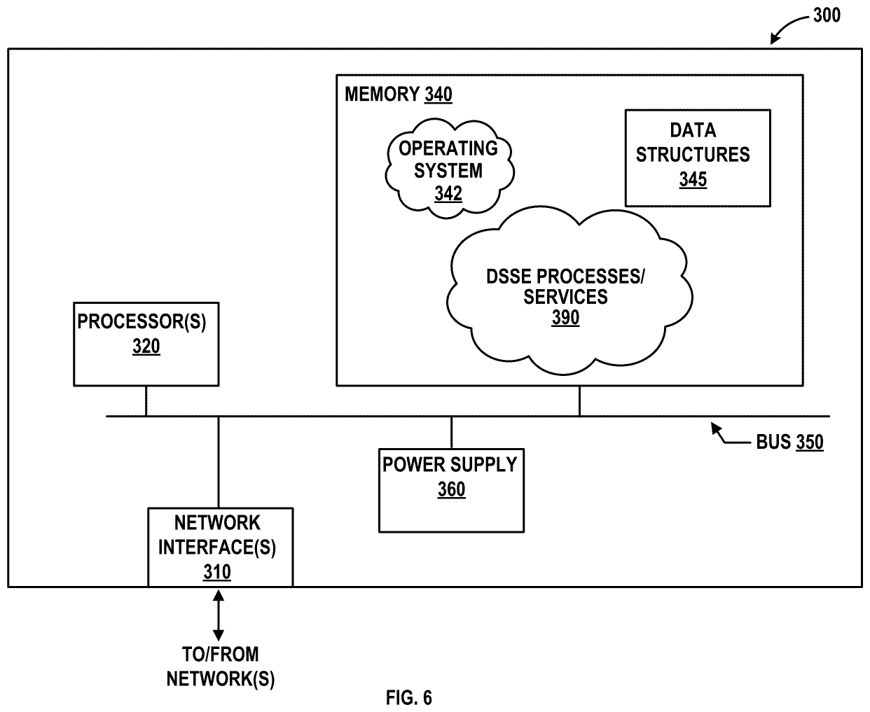

FIG. 6 is a schematic block diagram of an example device 300 that may be used with one or more embodiments described herein, e.g., implementing the system 100 shown in FIGS. 1A-1C and/or process 200 shown in FIG. 2.

Device 300 comprises one or more network interfaces 310 (e.g., wired, wireless, PLC, etc.), at least one processor 320, and a memory 340 interconnected by a system bus 350, as well as a power supply 360 (e.g., battery, plug-in, etc.).

Network interface(s) 310 include the mechanical, electrical, and signaling circuitry for communicating data over the communication links coupled to a communication network. Network interfaces 310 are configured to transmit and/or receive data using a variety of different communication protocols. As illustrated, the box representing network interfaces 310 is shown for simplicity, and it is appreciated that such interfaces may represent different types of network connections such as wireless and wired (physical) connections. Network interfaces 310 are shown separately from power supply 360, however it is appreciated that the interfaces that support PLC protocols may communicate through power supply 360 and/or may be an integral component coupled to power supply 360.

Memory 340 includes a plurality of storage locations that are addressable by processor 320 and network interfaces 310 for storing software programs and data structures associated with the embodiments described herein. In some embodiments, device 300 may have limited memory or no memory (e.g., no memory for storage other than for programs/processes operating on the device and associated caches). Memory 340 can include instructions executable by the processor 320 that, when executed by the processor 320, cause the processor 320 to implement aspects of the system and the methods outlined herein.

Processor 320 comprises hardware elements or logic adapted to execute the software programs (e.g., instructions) and manipulate data structures 345. An operating system 342, portions of which are typically resident in memory 340 and executed by the processor, functionally organizes device 300 by, inter alia, invoking operations in support of software processes and/or services executing on the device. These software processes and/or services may include DSSE processes/services 390, which can include aspects of system 100 and process 200 described herein and/or implementations of various modules described herein. Note that while DSSE processes/services 390 is illustrated in centralized memory 340, alternative embodiments provide for the process to be operated within the network interfaces 310, such as a component of a MAC layer, and/or as part of a distributed computing network environment.

It will be apparent to those skilled in the art that other processor and memory types, including various computer-readable media, may be used to store and execute program instructions pertaining to the techniques described herein. Also, while the description illustrates various processes, it is expressly contemplated that various processes may be embodied as modules or engines configured to operate in accordance with the techniques herein (e.g., according to the functionality of a similar process). In this context, the term module and engine may be interchangeable. In general, the term module or engine refers to model or an organization of interrelated software components/functions. Further, while the DSSE processes/services 390 is shown as a standalone process, those skilled in the art will appreciate that this process may be executed as a routine or module within other processes.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A method, comprising:
accessing a set of synchrophasor measurement device (SMD) observation data for a distribution network;
identifying, at a first deep neural network (DNN-TI), a present topology of the distribution network based on the set of SMD observation data; and
estimating, at a second deep neural network (DNN-DSSE) in communication with the first deep neural network (DNN-TI), an estimated state vector for a plurality of nodes of the distribution network.

2. The method of claim 1, where identifying the present topology of the distribution network based on the set of SMD observation data includes:
comparing the present topology of the distribution network with a base topology that was used to train the second deep neural network (DNN-DSSE).

3. The method of claim 2, further comprising:
fine-tuning one or more weights of the second deep neural network (DNN-DSSE) based on the present topology of the distribution network and based on a set of topology information stored at a transfer learning database that is associated with the present topology, the set of topology information including a set of three-phase power flow data and a set of error-modeled SMD data stored at a transfer learning database.

4. The method of claim 1, the second deep neural network (DNN-DSSE) being a regression-based deep neural network.

5. The method of claim 1, the first deep neural network (DNN-TI) being a classification-based deep neural network.

6. The method of claim 1, further comprising:
accessing a set of historical smart meter data for a distribution network;
iteratively sampling, by a Monte Carlo method, a topology of a set of feasible topologies of the distribution network; and
generating a set of modeled SMD data for the distribution network under the topology.

7. The method of claim 6, further comprising:
storing, for the topology of the set of feasible topologies, a set of topology information including a set of three-phase power flow data and the set of modeled SMD data for the distribution network at a transfer learning database.

8. The method of claim 6, further comprising:
training the first deep neural network (DNN-TI) to identify a topology of the distribution network based on a set of SMD observation data for the distribution network.

9. The method of claim 6, further comprising:
training the second deep neural network (DNN-DSSE) to perform a state estimation task under the topology of the set of feasible topologies based on a set of SMD observation data for the distribution network, the topology being a base topology of the distribution network.

10. The method of claim 6, further comprising:
generating, for the topology of the set of feasible topologies for the distribution network, a set of three-phase power flow data including a set of voltage phasors of a plurality of nodes of the distribution network under the topology;
generating, based on the set of three-phase power flow data and for the topology of the set of feasible topologies, a set of error-free SMD data for the distribution network; and
generating the set of modeled SMD data for the distribution network under the topology by augmenting the set of error-free SMD data to include measurement noise.

11. The method of claim 1, further comprising:
identifying one or more nodes of the distribution network for placement of SMDs.

12. The method of claim 11, where identifying the one or more nodes for placement of SMDs includes:
applying a sequential forward selection methodology to select the one or more nodes of the distribution network for SMD placement.

13. The method of claim 12, where identifying the one or more nodes for placement of SMDs includes:
receiving a minimum correlation value representative of a target minimum correlation between one or more nodes of the distribution network;
determining a Spearman Correlation Coefficient value between each respective modeled voltage phasor measurement;
constructing one or more Spearman Correlation Matrices based on the Spearman Correlation Coefficient value between each respective modeled voltage phasor measurement;
applying a hierarchical clustering methodology to the one or more Spearman Correlation Matrices to obtain one or more clusters; and
selecting a common node of the one or more nodes of the distribution network in each cluster of the one or more clusters for SMD placement.

14. A system, comprising:
a processor in communication with a memory, the memory including instructions executable by the processor to:
access a set of synchrophasor measurement device (SMD) observation data for a distribution network;
identify, at a first deep neural network (DNN-TI), a present topology of the distribution network based on the set of SMD observation data; and
estimate, at a second deep neural network (DNN-DSSE) in communication with the first deep neural network (DNN-TI), an estimated state vector for a plurality of nodes of the distribution network.

15. The system of claim 14, the memory further including instructions executable by the processor to:
compare the present topology of the distribution network with a base topology that was used to train the second deep neural network (DNN-DSSE).

16. The system of claim 14, the memory further including instructions executable by the processor to:
fine-tune one or more weights of the second deep neural network (DNN-DSSE) based on the present topology of the distribution network and based on a set of topology information stored at a transfer learning database that is associated with the present topology, the set of topology information including a set of three-phase power flow data and a set of error-modeled SMD data stored at a transfer learning database.

17. The system of claim 14, the memory further including instructions executable by the processor to:
access a set of historical smart meter data for a distribution network;
iteratively sample, by a Monte Carlo method, a topology of a set of feasible topologies of the distribution network; and
generate a set of modeled SMD data for the distribution network under the topology.

18. The method of claim 17, the memory further including instructions executable by the processor to:
store, for the topology of the set of feasible topologies, a set of topology information including a set of three-phase power flow data and the set of modeled SMD data for the distribution network at a transfer learning database.

19. The system of claim 14, the memory further including instructions executable by the processor to:
train the first deep neural network (DNN-TI) to identify a topology of the distribution network based on a set of SMD observation data for the distribution network; and
train the second deep neural network (DNN-DSSE) to perform a state estimation task under the topology of the set of feasible topologies based on the set of SMD observation data for the distribution network, the topology being a base topology of the distribution network.

20. A non-transitory, computer-readable medium storing instructions encoded thereon, the instructions, when executed by one or more processors, cause the one or more processors to perform operations to:
access a set of synchrophasor measurement device (SMD) observation data for a distribution network;
identify, at a first deep neural network (DNN-TI), a present topology of the distribution network based on the set of SMD observation data; and
estimate, at a second deep neural network (DNN-DSSE) in communication with the first deep neural network (DNN-TI), an estimated state vector for a plurality of nodes of the distribution network.
